(19) United States
(12) Patent Application Publication
(10) Pub. No.: US 2013/0157403 A1
(43) Pub. Date: Jun. 20, 2013

(54) COMPOUNDS FOR PHOTOVOLTAICS

(71) Applicants: Sheena Zuberi, Harrow (GB); Tania Zuberi, Harrow (GB)

(72) Inventors: Sheena Zuberi, Harrow (GB); Tania Zuberi, Harrow (GB)

(73) Assignee: CAMBRIDGE DISPLAY TECHNOLOGY LIMITED, Cambridgeshire (GB)

(21) Appl. No.: 13/820,508

(22) PCT Filed: Sep. 2, 2011
(86) PCT No.: PCT/GB11/01293

§ 371 Date: Mar. 2, 2013

(30) Foreign Application Priority Data
Sep. 3, 2010 (GB) 1014672.8

(51) Int. Cl. H01L 51/00

(52) U.S. Cl. CPC H01L 51/0036; H01L 51/0071; H01L 51/0074; H01L 51/0005
USPC 438/82; 548/126; 544/342; 549/43; 549/41; 546/41; 546/31; 526/256; 526/257; 252/500

(57) ABSTRACT

A species for use, for example, in a charge transfer layer of a photovoltaic device, the species comprising an acceptor group to which is fused a tuning group. The species can be a small molecule, polymer or oligomer, and monomers for producing said polymer, photovoltaic devices comprising said species, and methods for producing said device, are also provided.

The present invention relates to semiconducting polymers and particularly but not exclusively to polymers suitable for inclusion in photovoltaic devices and to those devices.

Organic semiconductors are becoming increasingly utilised in place of their inorganic counterparts. In particular, organic semiconductors have been incorporated into devices such as light emitting diodes (LEPs), photovoltaic diodes (PVs), lasers and field effect transistors (FETs).

While many organic semiconductors consists of small molecules, polymeric organic semiconductor materials have an advantage in that they may be solution processable, thereby providing the flexibility of device manufacture which is afforded by solution processing techniques such as printing or spin coating.

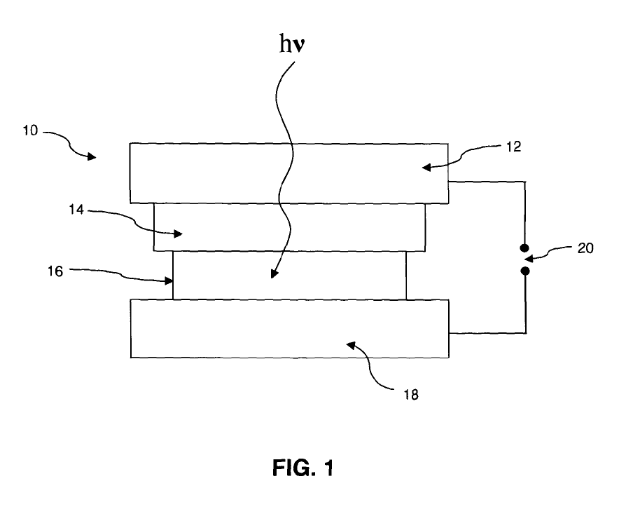

A typical prior art organic photovoltaic cell 10 is shown in FIG. 1.

The cell comprises a number of layers, in series, an indium tin oxide (ITO) electrode 12, a layer of Poly (3,4-ethylene dioxythiophene) poly (styrene sulfonate) PEDOT:PSS) 14, an active layer 16 and an aluminium electrode 18. The aluminium electrode may in turn be laid down on a polymer substrate, such as a polyethylene terephthalate substrate (not shown) and the ITO electrode may be protected by a transparent layer (not shown). The electrodes 12, 18 are connected to a power outlet 20.

The active layer 16 commonly comprises a highly conjugated polymer species which has delocalised Π electrons. When a photon is absorbed by the species, an electron in the delocalised Π orbital, the highest occupied molecular orbital (HOMO), transfers to the lowest unoccupied molecular orbital (LUMO) or Π** orbital, creating an excited state.

This excited state can be regarded as an electron hole pair bound by electrostatic and lattice interaction, and is termed an “exciton”. The excitons are typically confined to so-called “donor groups”.

Excitons are unbound in the active layer 10 by provision of electron acceptors which provide an interface across which the chemical potential of the electrons decrease. Typically the electron is accepted by the LUMO of the acceptor group.

Donor groups and acceptor groups have often been provided in the active layer 10 by mixing donor group carrying polymers and electron accepting fullerenes.

More recently, attempts have been made to incorporate donor groups and acceptor groups onto the same molecule and/or to incorporate band-gap reducing groups into the acceptor carrying molecule.

For example, Tsami, et al in J. Mat. Chem. 2007 (17) 1353-1355 provide a polymer of the structure:

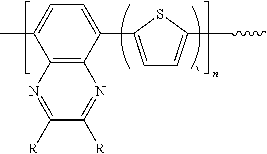

McNeil et al in Appl. Phys. Lett. 2007 (90) 193506 provide a polymer of the structure:

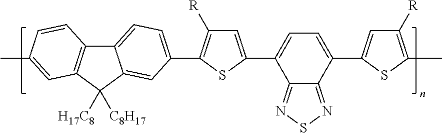

Yang et al in Macromolecules 2005 (38) 244-253 describe a polymer having the structure:

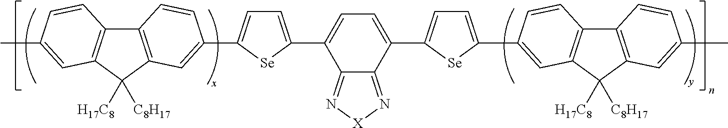

Liu et al in Macromolecules 2005 (38) 716-721 describe polymers having the structure:

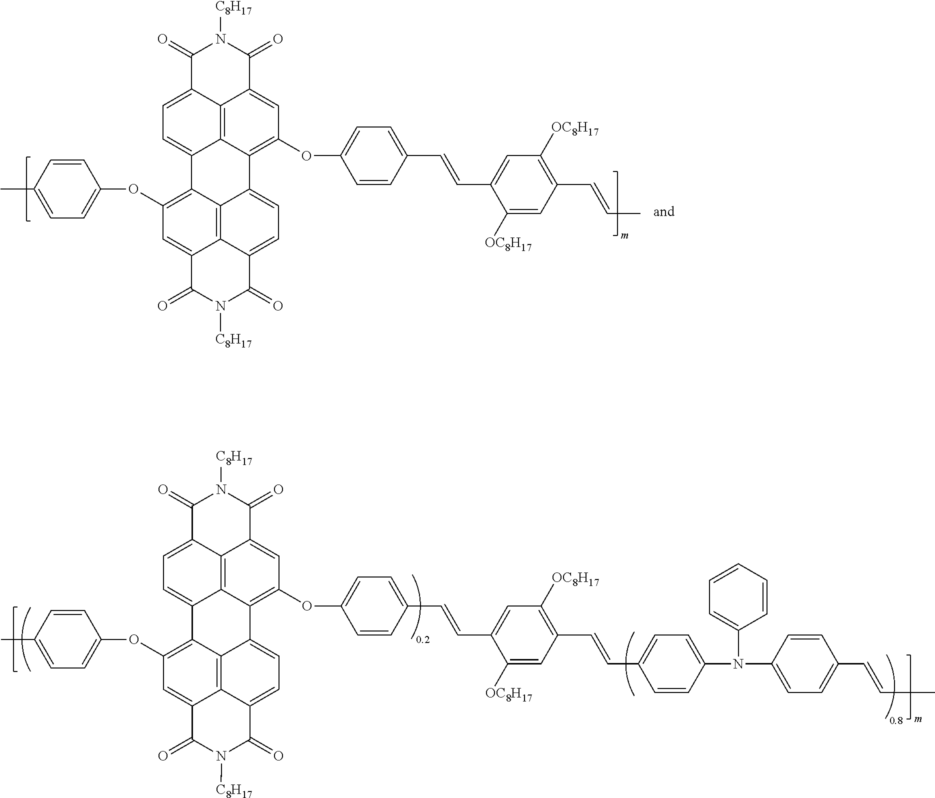

Zhu et al in Macromolecules 2006 (39) 8712-8719 describe polymers having the structures:

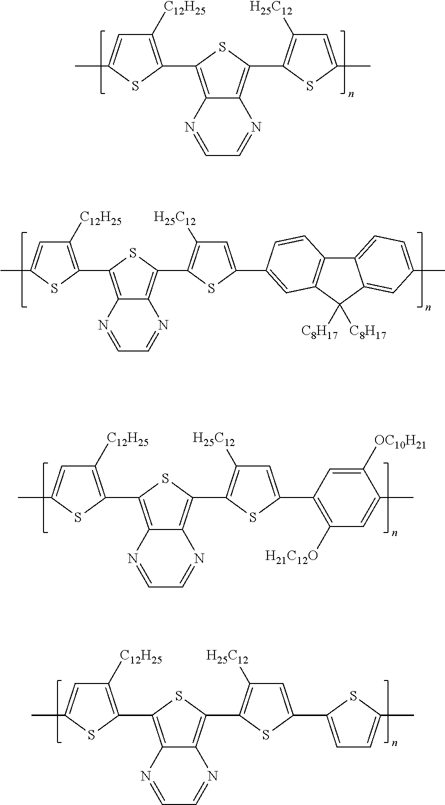

Zhu et al in Macromolecule 2007 (40) 1981-1986 describe polymers of the form:

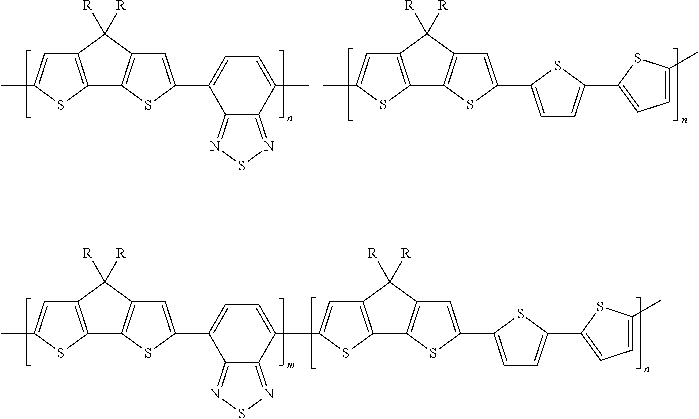

Hou et al in J. Mat. Chem. 2002 (12) 2887-2892 describe a polymer of the form:

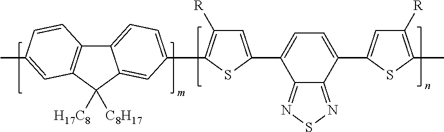

Shi et al in J. Am. Chem. Soc 2006 (128) 8980-8986 describe a polymer of the form:

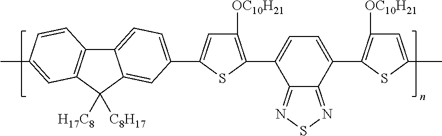

Blanco et al in Org. Lett. 2007 (9/11) 2171-2174 describe a polymer having the structure:

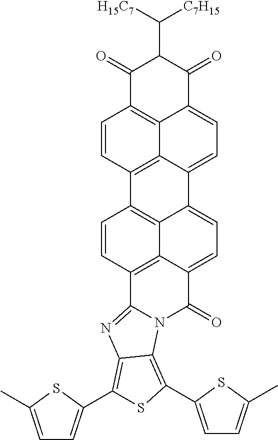

It is an object of the present invention to provide a charge transfer species which has improved electron/hole mobility.

It is a further non-exclusive object of the invention to provide a charge transfer species which has a reduced band gap such as a reduced band gap in the acceptor group. It is a further object of the invention to provide a photovoltaic device having improved efficiency.

Accordingly, in a first aspect, the invention provides a species for use in a change transfer layer of a photovoltaic device, the species comprising an acceptor group, wherein at least one tuning group is fused to the acceptor group.

The fusing of the tuning and acceptor groups allows for increased conjugation of the system, giving improved mobilities and a reduced band gap.

The tuning group is a conjugated ring structure which, when fused to the acceptor group, alters, e.g. decreases, the band gap of the acceptor.

Preferably, the tuning group has a HOMO level, in isolation from the acceptor group, of at least 4.5 eV, for example at least 5 eV, e.g. at least 5.2 eV.

Preferably the acceptor group comprises at least one acceptor conjugated ring structure, which may be an aromatic structure.

Preferably, the or an acceptor conjugated ring structure is fused to one or more tuning groups, preferably via the or a tuning conjugated ring structure.

Preferably the acceptor group comprises a structure selected from the group comprising:

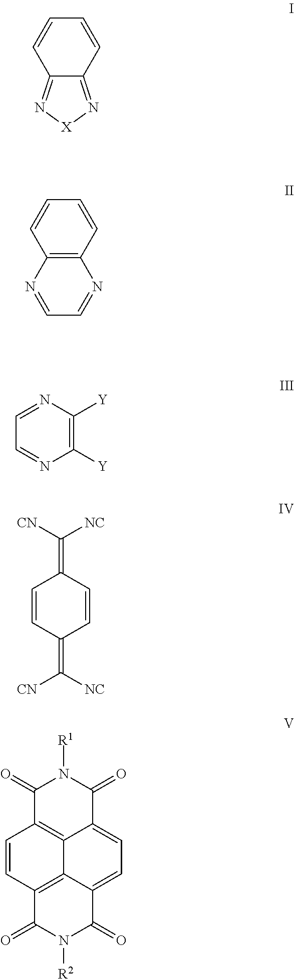

where X is S or O and where R¹ and R² are the same or different and comprise H or optionally substituted, straight, branched or cyclic alkyl or alkenyl chains with 1 to 20 carbon atoms, alkoxy, amino, amide, silyl, alkyl silyl or acyl groups, and where Y comprises halogen, nitrile or any electron withdrawing group (EWG).

The tuning groups preferably comprise at least one thiophene ring. The thiophene ring is preferably fused directly to the acceptor group, although may be fused to the acceptor group via one or more conjugated, e.g. aromatic, ring structures.

The tuning group may comprise two or more conjugated ring structures of which at least one may be a thiophene ring. For example, the tuning groups may comprise a structure selected from the group comprising:

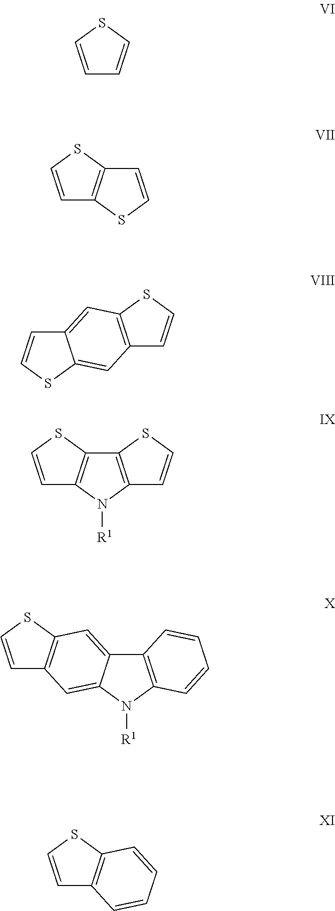

or diastereoisomers thereof.

The tuning groups may be substituted at one or more available carbons.

Preferably the tuning groups are substituted by one or more groups, which may be the same or different, selected form the group comprising optionally substituted straight branched or cyclic alkyl or alkenyl chains with 1 to 20 carbon atoms, alkoxy amino, amide, silyl, alkenyl, alkyl and alkyl silyl.

The acceptor groups may also be substituted at one or more available carbon atom, preferably with a substituent group Y. Substituent group Y is preferably selected from the group comprising: halogen, nitrile, or any electron withdrawing group (EWG).

In some embodiments the species is a small molecule. Such a small molecule may further comprise solvating groups such as alkyl chains and/or silyl groups. Such groups may be joined to the species by means of alkenyl and/or aklynyl linker groups.

In alternative embodiments, the species may comprise a polymeric species, such as a polymer, dendrimer, or oligomer.

Preferably at least part of one or both of the tuning groups and the acceptor groups form a part of the polymer backbone.

Preferably the species is a copolymeric species, preferably comprising fluorene or fluorene based repeat units.

In a further aspect, the invention provides a monomeric species comprising a species as described above, the species substituted with two or more reactive groups.

Preferably the reactive groups comprise halogens and/or boronic esters such as maybe provided for performing a Suzuki reaction.

In another embodiment, the reactive groups may comprise halogens and/or organotin groups such as may be provided for performing a Stille reaction.

In another aspect, the invention provides a polymer for use in a charge transfer layer of a photovoltaic device, the polymer comprising a repeat unit comprising a species as described above.

Preferably the polymer is a copolymer.

Preferably the polymer further comprises repeat units comprising fluorene residues.

In a further aspect the invention comprises a solution for forming a change transfer layer of a photovoltaic device, the solution having a solute comprising a species or a polymer as described above.

Preferably, the solution further comprises a donor species, e.g. a donor polymer such as poly(3-hexylthiophene-2,5-diyl), (P3HT).

In another aspect, the invention provides a method for forming a photovoltaic device, the method comprising applying a solution as described above to a substrate.

Preferably the solution is applied to the substrate by a means selected from the group comprising: inkjet printing, spin coating.

In another aspect the invention provides a photovoltaic device comprising a charge transfer layer comprising a species or a polymer as described above.

Preferably, the charge transfer layer further comprises a donor species, e.g. a donor polymer such as poly(3-hexylthiophene-2,5-diyl).

The invention will now be described in more detail by reference to the following drawings and non-limiting examples.

FIG. 1 shows a structure of a photovoltaic cell.

A photovoltaic cell 10, as shown in FIG. 1 has, in series, an ITO electrode 12, a PEDOT:PSS layer 14, an active layer 16 and an aluminium electrode 18. A power output 20 is provided across the electrodes 12, 18 in a similar manner to a constructive of the prior art.

The active layer 16 comprises a tuned acceptor polymer for converting incident light into electric power, blended with a donor system such as poly(3-hexylthiophene-2,5-diyl), (P₃HT).

The tuned acceptor polymer is a conjugated fluorene copolymer comprising, e.g. 50% dioctyl fluorene and, for example, 50% of one of the following species:

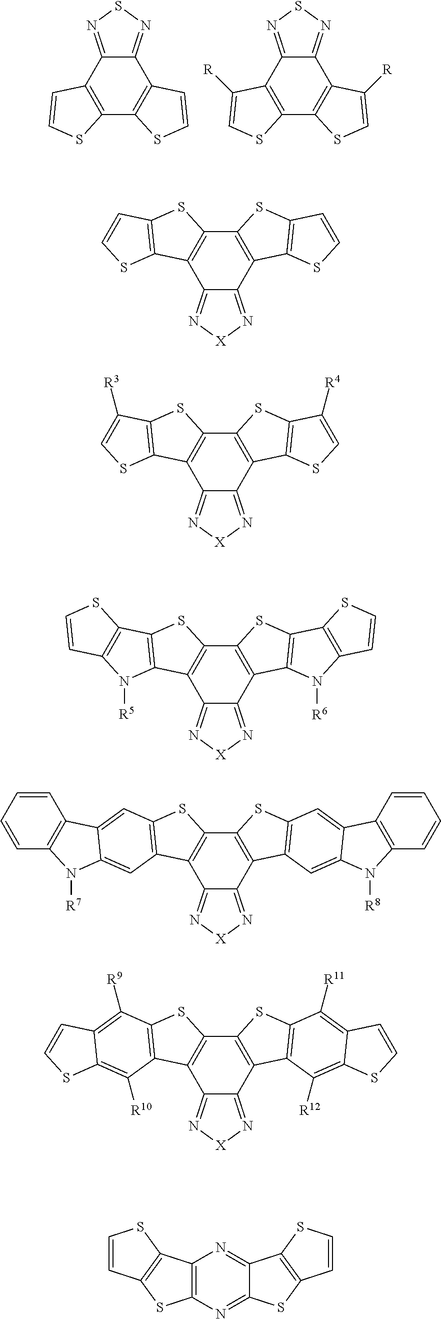

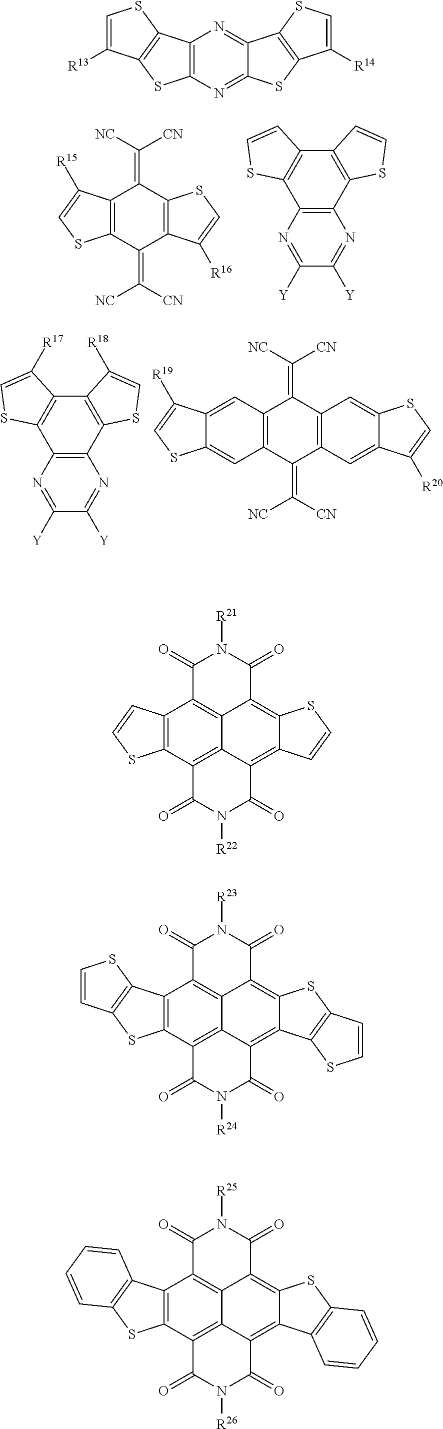

where X is S or O, where Y is F, CN or another electron withdrawing group and R³ to R²⁶ are the same or different and comprise C₁ to C₂₀ optionally substituted, straight, branched or cyclic alkyl, alkenyl, alkynyl aromatic, alkoxy amino or amido groups.

No doubt many other effective alternatives will occur to the skilled person. It will be understood that the invention is not limited to the described embodiments and encompasses modifications apparent to those skilled in the art lying within the spirit and scope of the claims appended hereto.

1. A species for use in a charge transfer layer of a photovoltaic device, the species comprising an acceptor group, wherein a tuning group is fused to the acceptor group.

2. A species according to claim 1, wherein the acceptor group comprises at least one acceptor conjugated ring structure.

3. A species according to claim 1, wherein the tuning group comprises at least one donor conjugated ring structure.

4. A species according to claim 1, wherein the tuning group has a HOMO level, in isolation from the acceptor group, of at least 4.5 eV.

5. A species according to claim 2, wherein the or an acceptor conjugated ring structure is fused to one or more tuning groups.

6. A species according to claim 1, wherein the acceptor group comprises a structure selected from the group consisting of: 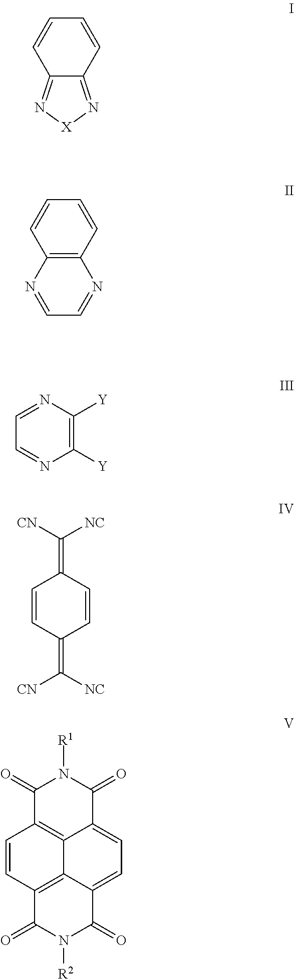
where X is S or O and where R¹ and R² are the same or different and comprise H or optionally substituted, straight, branched or cyclic alkyl or alkenyl chains with 1 to 20 carbon atoms, alkoxy, amino, amide, silyl, alkyl silyl or acyl groups, and where Y comprises halogen, nitrile or any electron withdrawing group (EWG).

7. A species according to claim 1, wherein the tuning group comprises at least one thiophene ring.

8. A species according to claim 7, wherein the thiophene ring is fused directly to the acceptor group or is fused to the acceptor group via one or more conjugated ring structures.

9. A species according to claim 7, wherein the tuning group comprises two or more conjugated ring structures of which at least one is a thiophene ring.

10. A species according to claim 7, wherein the tuning groups comprise a structure selected from the group consisting of: 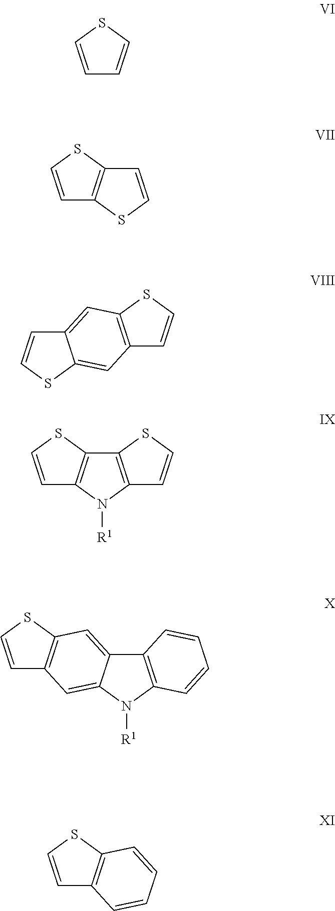
and diastereoisomers thereof, where R¹ comprises H or optionally substituted, straight, branched or cyclic alkyl or alkenyl chains with 1 to 20 carbon atoms, alkoxy, amino, amide, silyl, alkyl silyl or acyl groups.

11. A species according to claim 1, wherein the tuning group is substituted at one or more available carbons.

12. A species according to claim 11, wherein the tuning group is substituted by one or more groups, which may be the same or different, selected from the group consisting of optionally substituted straight branched or cyclic alkyl or alkenyl chains with 1 to 20 carbon atoms, alkoxy amino, amide, silyl, alkenyl, alkyl and alkyl silyl.

13. A species according to claim 1, wherein the acceptor group is substituted at one or more available carbon atom.

14. A species according to any of claim 1 comprising a structure selected from the group consisting of: 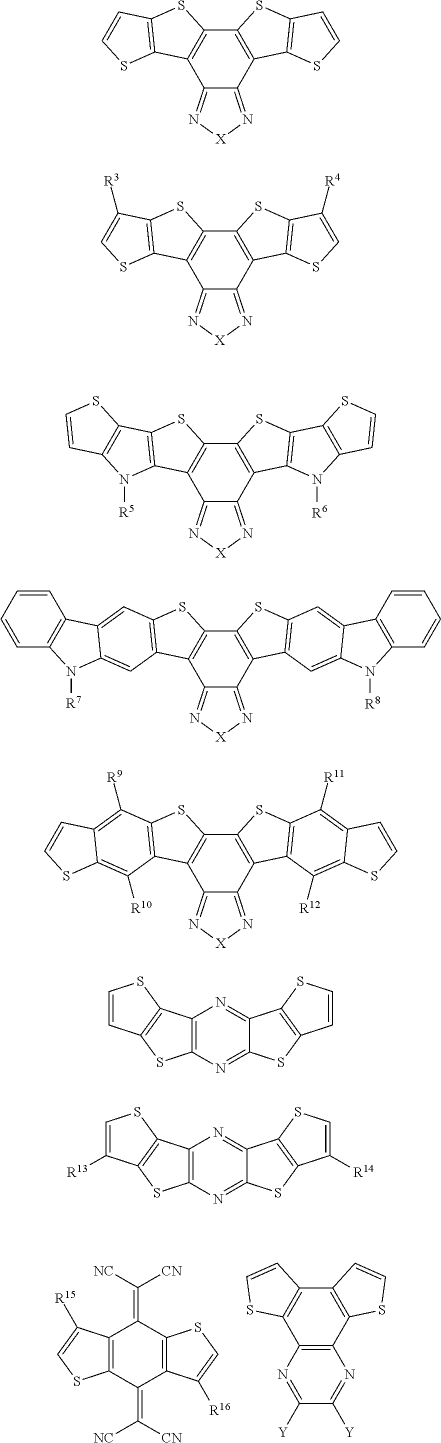 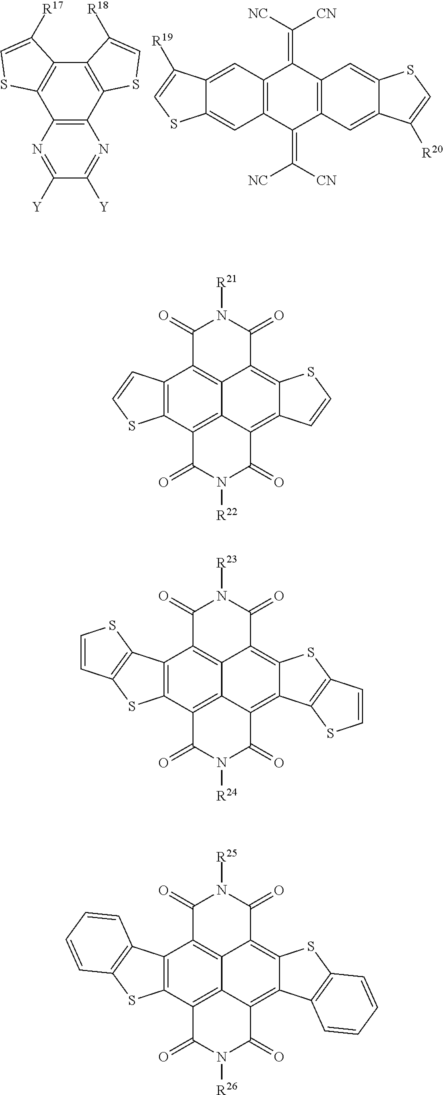
where X is S or O, where Y is F, CN or another electron withdrawing group and R³ to R²⁶ are the same or different and comprise C₁ to C₂₀ optionally substituted, straight, branched or cyclic alkyl, alkenyl, alkynyl, aromatic, alkoxy, amino or amido groups.

15. A species according to claim 1 where the species is a small molecule.

16. A species according to claim 15 wherein the small molecule further comprises solvating groups.

17. A species according to any of claim 1, wherein the species comprises a polymeric species.

18. A species according to claim 17, wherein at least part of one or both of the tuning group and the acceptor group lie in the polymer backbone.

19. A species according to claim 17, wherein the species is a copolymeric species.

20. A species according to claim 19, wherein the copolymer comprises between 30 mol % and 70 mol % fluorene residues.

21. A monomeric species comprising a residue comprising an acceptor group, wherein a tuning group is fused to the acceptor group, the species substituted with two or more reactive groups.

22. A monomeric species according to claim 21, wherein the reactive groups comprise halogens and/or boronic esters.

23. A monomeric species according to claim 21, wherein the reactive groups comprise halogens and/or organotin groups.

24. A polymer for use in a charge transfer layer of a photovoltaic device, the polymer comprising a first repeat unit comprising an acceptor group, wherein a tuning group is fused to the acceptor group.

25. A polymer according to claim 24, further comprising a second repeat unit comprising a fluorene residue.

26. A polymer according to claim 25, wherein the molar ratio of first repeat unit to second repeat unit is between 30%:70% and 70%:30%.

27. A polymer according to claim 25 comprising a third repeat unit and optionally a fourth and/or fifth and/or sixth repeat unit.

28. A solution for forming a change transfer layer of a photovoltaic device, the solution having a solute comprising a species according to claim 1.

29. A solution according to claim 28, further comprising a donor species.

30. A method for forming a photovoltaic device, the method comprising applying the solution according to claim 28 to a substrate.

31. A method according to claim 30, wherein the solution is applied to the substrate by inkjet printing or spin coating.

32. A photovoltaic device comprising a charge transfer layer comprising a species according to claim 1.

33. A photovoltaic device according to claim 32, wherein the charge transfer layer further comprises a donor species.

34. A photovoltaic device according to claim 33, wherein the donor species comprises a donor polymer.

35. A photovoltaic device according to claim 33, wherein the donor species comprises poly(3-hexylthiophene).

36. A species according to claim 17, wherein the polymeric species is selected from the group consisting of a polymer, a dendrimer, and an oligomer.
